(19) United States
(12) Patent Application Publication
(10) Pub. No.: US 2007/0216037 A1
(43) Pub. Date: Sep. 20, 2007

(54) Memory card structure and method for manufacturing the same

(76) Inventors: Dennis Pai, Hsinchu Hsien (TW); Hong Tsu Chang, Hsinchu Hsien (TW); Potter Chien, Hsinchu Hsien (TW); Jay Lin, Hsinchu Hsien (TW); Roy Lin, Hsinchu Hsien (TW)

Correspondence Address: PRO-TECHTOR INTERNATIONAL SERVICES, 20775 NORADA CT., SARATOGA, CA, 95070, US

(21) Appl. No.: 11/378,793

(22) Filed: Mar. 16, 2006

(51) Int. Cl. H01L 23/48

(52) U.S. Cl. 257/783; 257/E23.127

(57) ABSTRACT

A memory card structure includes a substrate, B-Stage glue, an adhered layer, a chip, wires, and a compound layer. The substrate has an upper surface, which is formed with first electrodes and golden fingers electrically connected to the first electrodes. The B-Stage glue is coated on the periphery of upper surface of the substrate. The adhered layer is coated on the upper surface of the substrate. The chip is formed with bonding pads, and is adhered on the upper surface of the substrate by the B-Stage glue and the adhered layer. The plurality of wires are electrically connected the bonding pads of the chip to the first electrodes of the substrate. And the compound layer is encapsulated on the chip and the wires.

### BACKGROUND OF THE INVENTION

1. Field of the Invention

The invention relates a memory card structure and a method for manufacturing the same, and particular to a structure for packaging memory card, the reliability may be increased.

2. Description of the Related Art

Referring to FIG. 1, a conventional memory card structure includes a substrate 10, an adhered layer 22, a chip 24, wires 28, and a compound layer 30.

The substrate 10 has an upper surface 12, which is formed with first electrodes 16 and golden fingers 18 electrically connected to the first electrodes 16, and passive component 20. The adhered layer 22 is coated on the upper surface 12 of the substrate 10. The chip 24 is formed with bonding pads 26, and is adhered on the upper surface 12 of the substrate 10 by the adhered-layer 22. The plurality of wires 28 are electrically connected the bonding pads 26 of the chip 24 to the first electrodes 16 of the substrate 10. And the compound layer 30 is encapsulated on the chip 24 and the wires 28.

### SUMMARY OF THE INVENTION

An objective of the invention is to provide a memory card structure and a method for manufacturing the same, and capable of increasing the reliability of the structure.

To achieve the above-mentioned object, the invention includes a substrate, B-Stage glue, an adhered layer, a chip, wires, and a compound layer. The substrate has an upper surface, which is formed with first electrodes and golden fingers electrically connected to the first electrodes. The B-Stage glue is coated on the periphery of upper surface of the substrate. The adhered layer is coated on the upper surface of the substrate. The chip is formed with bonding pads, and is adhered on the upper surface of the substrate by the B-Stage glue and the adhered layer. The plurality of wires are electrically connected the bonding pads of the chip to the first electrodes of the substrate. And the compound layer is encapsulated on the chip and the wires.

### BRIEF DESCRIPTION OF THE DRAWINGS

FIG. 1 is a schematic illustration showing a conventional memory card structure.

FIG. 2 is a cross-sectional schematic illustration showing a memory card structure of the present invention.

FIG. 3 is a first schematic illustration showing a memory card structure of the present invention.

FIG. 4 is a second schematic illustration showing a memory card structure of the present invention.

FIG. 5 is a third schematic illustration showing a memory card structure of the present invention.

FIG. 6 is a fourth schematic illustration showing a memory card structure of the present invention.

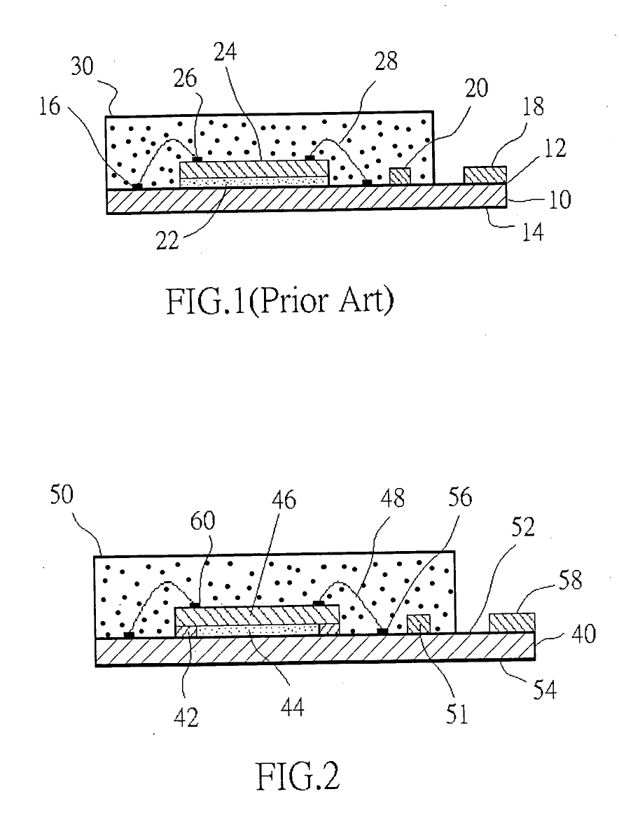

### DETAILED DESCRIPTION OF THE INVENTION

Please refer to FIG. 2, a memory card structure includes a substrate 40, B-Stage glue 42, an adhered layer 44, a chip 46, wires 48, and a compound layer 50.

The substrate 40 has an upper surface 52, which is formed with first electrodes 56, and golden fingers 58 electrically connected to the first electrodes 56, and passive component 51.

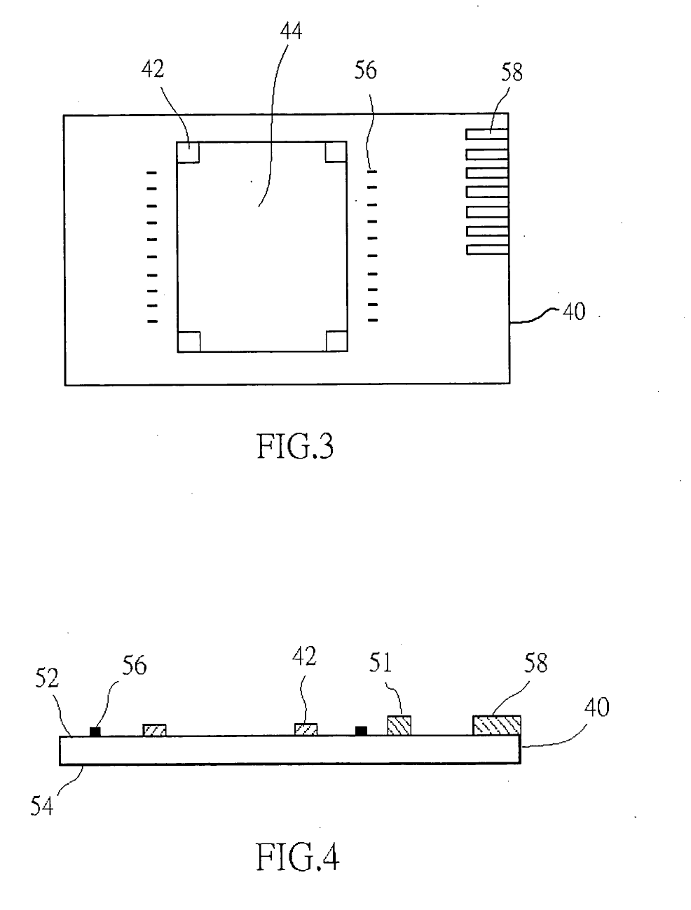

Please refer to FIG. 3. The B-Stage glue 42 is coated on the four corner of the upper surface 52 of the substrate 40.

The adhered layer 44 is form of epoxy, and is coated on the upper surface 52 of the substrate 40.

The chip 46 is formed with bonding pads 60, and is adhered on the upper surface 52 of the substrate 40 by the B-Stage glue 42 and the adhered layer 44.

The plurality of wires 48 are electrically connected the bonding pads 60 of the chip 46 to the first electrodes 56 of the substrate 40. And

The compound layer 50 is encapsulated on the chip 46 and the wires 48.

Please refer to FIG. 4, a method for manufacturing a memory card structure of the invention includes the steps of:

Providing a substrate 40, which has an upper surface 52, on which first electrode 56 is formed, and golden fingers 58 is electrically connected to the first electrodes 56, and passive component 51.

Providing B-Stage glue 42, which is coated on the four corner of the upper surface 52 of the substrate 40 to cure in 120 C. for one hour.

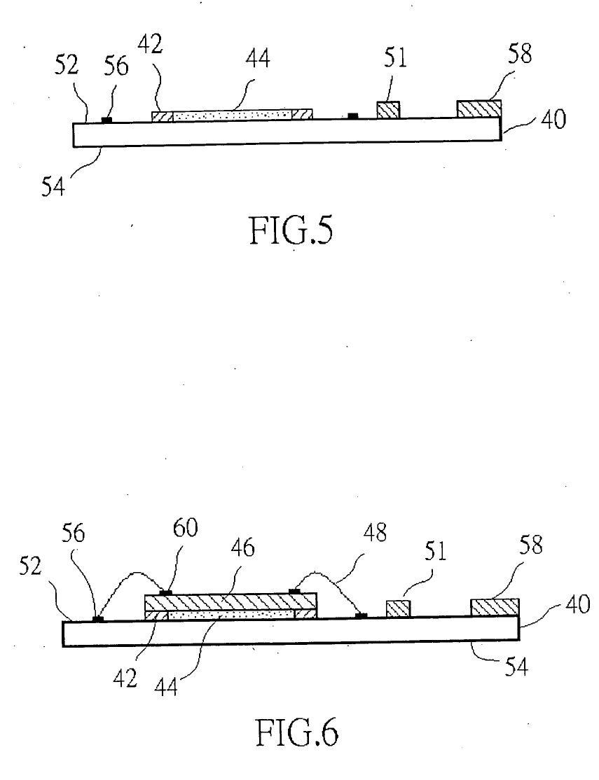

Please refer to FIG. 5. Providing an adhered layer 44, which is form of epoxy, and is coated on the upper surface 52 of the substrate 40.

Please refer to FIG. 6. Providing a chip 46, which is formed with bonding pads 60, and is adhered on the upper surface 52 of the substrate 40 by the B-Stage glue 42 and the adhered layer 44.

Providing wires 48, which are electrically connected the bonding pads 60 of the chip 46 to the first electrodes 56 of the substrate 40. And

Please refer to FIG. 2. Providing a compound layer 50, which is encapsulated on the chip 46, passive component 51, and the wires 48.

The memory card structure and manufacturing method in accordance with the embodiments of the invention have the advantages as follows.

1. Since the chip 46 may effectively adhered to the substrate 40 by B-Stage glue 42, so that the substrate 40 may be press to smooth, therefore, the reliability of the memory may be increased.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. A memory card structure, the structure comprising:
a substrate having an upper surface, which is formed with first electrodes and golden fingers electrically connected to the first electrodes;
a B-Stage glue coated on the periphery of upper surface of the substrate;
an adhered layer coated on the upper surface of the substrate;
a chip formed with bonding pads, and adhered on the upper surface of the substrate by the B-Stage glue and the adhered layer;
a plurality of wires electrically connected the bonding pads of the chip to the first electrodes of the substrate; and
a compound layer encapsulated on the chip and the wires.

2. The memory card structure according to claim 1, wherein the substrate is formed with passive component.

3. The memory card structure according to claim 1, wherein the adhered layer is form of epoxy.

4. A method for manufacturing the memory card structure, comprising the steps of:
Providing a substrate having an upper surface, which is formed with first electrodes and golden fingers electrically connected to the first electrodes;
Providing a B-Stage glue coated on the periphery of upper surface of the substrate;
Providing an adhered layer coated on the upper surface of the substrate;
Providing a chip formed with bonding pads, and adhered on the upper surface of the substrate by the B-Stage glue and the adhered layer;
Providing a plurality of wires electrically connected the bonding pads of the chip to the first electrodes of the substrate; and
Providing a compound layer encapsulated on the chip and the wires.

5. The method according to claim 4, wherein the substrate is formed with passive component.

6. The method according to claim 4, wherein the adhered layer is form of epoxy.

7. The method according to claim 4, wherein the B-Stage glue is coated on the substrate by printing.
